(19) United States
(12) Patent Application Publication
(10) Pub. No.: US 2016/0294334 A1
(43) Pub. Date: Oct. 6, 2016

(54) Circuit arrangement and apparatus for protecting an electronic component

(71) Applicants: Helmut Piel, Wuppertal (DE); Sergei Kolesov, Gevelsberg (DE)

(72) Inventors: Helmut Piel, Wuppertal (DE); Sergei Kolesov, Gevelsberg (DE)

(73) Assignee: CRYOELECTRA GMBH, Wuppertal (DE)

(21) Appl. No.: 14/674,181

(22) Filed: Mar. 31, 2015

(51) Int. Cl. H03F 1/52; H03H 7/01; H05H 13/00; H03F 3/19; H03F 3/21

(52) U.S. Cl. CPC H03F 1/52; H03F 3/19; H03F 3/211; H05H 13/00; H03H 7/0115; H03H 7/0161; H03F 2203/21106

(57) ABSTRACT

The invention relates, amongst others, to a circuit arrangement comprising a pass-through filter section between a first input and/or output node and a second input and/or output node, wherein a pass-through filter with low-pass characteristics is arranged in said pass-through filter section, a first absorption filter section between said first input and/or output node and a third node, wherein a first high-pass filter is arranged in said first absorption filter section, and wherein a first load resistance is arranged at said third node, and a second absorption filter section between said first input and/or output node and a fourth node, wherein a second high-pass filter is arranged in said second absorption filter section, and wherein a second load resistor is arranged at said fourth node.

### AREA OF THE INVENTION

The present invention inter alia relates to a circuit arrangement and an apparatus for protecting an electronic component, in particular a high-frequency component (e.g. for an amplifier unit of an HF amplifier or a VHF amplifier).

### BACKGROUND OF THE INVENTION

The acceleration of electrons, protons and heavy ions to high energies of several MeVs or more is carried out exclusively in the cavity resonators of a particle accelerator. To excite the electro-magnetic fields in these accelerator resonators, and to transfer the energy to the electrons, protons and ions to be accelerated, as well as to their anti-particles, high-frequency amplifiers in the HF range, from approx. 30 MHz to approx. 3 GHz (particularly in the VHF range from approx. 30 MHz to approx. 300 MHz), are required, which are able to deliver high-frequency power of approx. 10 kW up to several MW.

Until a few years ago, this kind of power could only be achieved using tube amplifiers. The successful development of LDMOS-FET (Laterally Diffused Metal Oxide Semiconductor-Field Effect Transistor) power transistors has meant that today VHF semi-conductor amplifiers can be built that deliver in the power range of 10 to 150 kW and beyond.

### SUMMARY OF SOME EXEMPLARY EMBODIMENTS OF THE PRESENT INVENTION

In the high frequency resonators of accelerator installations, electro-magnetic interference can occur, leading to interference signals or electromagnetic pulses that display partial wave frequencies that may lie above and/or below the operational frequency of the accelerator resonator, that are emitted by the accelerator resonator flowing towards the active power transistors, and they are able to destroy these. This damage is caused primarily by the high voltage amplitudes of interference signals (e.g. interference signals with voltage amplitudes of 130 V or more, in particular those with voltage amplitudes of 150 V or more). Pulse voltage amplitudes of more than 130 V and a duration of a few pico-seconds can destroy the power transistors of an HF amplifier, such as LDMOS field-effect transistors.

This interference is triggered in particular by self-maintaining gas discharges (electric arcs) in the accelerator resonators. The electrical arcs caused on circuits in electrical energy technology by switching-operations are known as ‘switch arcs’ and undesired electrical arcs are known as ‘interference arcs’. Such interference arcs can also occur in accelerator resonators.

It is in the nature of accelerator resonators that they have high electric field levels in their inner zones. To avoid interference arcs, a very good vacuum must therefore be maintained in the resonator. But an increase in local pressure in the resonator, that then creates the necessary preconditions for the creation of a self-maintaining gas discharge and interference arcs can occur while working with high energy fields, by field emission of electrons, or due to so-called electron multipacting.

In both these processes, streams of free electrons are generated, that are accelerated in the field of the resonator and thereby absorb more energy. When these electron streams collide with the wall of the resonator, heat is generated locally. This means that the resonator walls' adsorbed layers (primarily water coating) evaporate and can create the necessary gas to trigger a self-maintaining gas discharge (namely an arc). Both the processes that are able to create free streams in the resonator are described briefly below.

The phenomenon of creating streams of free electrons through multipacting generally occurs even at low field strengths in an accelerator resonator.

There are two types of electron multipacting: Single-surface and two-surface multipacting, the detailed description of which goes well beyond the scope of this submission. An electron multipacting event starts with the release of an electron from the copper wall of the resonator, typically by cosmic radiation. The electron leaving the metal is accelerated in the field of the resonator and in the case of two-surface multipacting collides with the opposite wall of the resonator. If its energy on penetrating the metal is greater than approx. 20 eV, then it may release several electrons from the metal. If at this time the direction of the electrical field on the surface of the metal has reversed, then the released electrons are accelerated back to the place where the original electron was released and in turn release further electrons. If the electrons' flight time between these two locations are exactly equal to (2n−1)*t/2, where n is an integer and t is the pulse duration of the high-frequency field, then the released electrons are again accelerated and in turn release more secondary electrons as they penetrate the metal.

The result of this avalanche effect is to create a significant stream, where both the limited surface areas that are affected are strongly heated. This heating can, as described above, lead to the evaporation of the layers that adhere to any metal surface (in particular water coatings) which in turn affects the local vacuum creating a gas discharge, which can then cause an interference arc. But the pre-requisite for this is that the multipacting process takes place in an area of the resonator where an electric field exists of sufficient strength to cause a self-perpetuating gas discharge and therefore an interference arc. Free streams of electrons in any event remove energy from the resonator field and therefore lead to a reduction in the quality of the resonator. This in turn leads to mismatch of the resonator and so to the high frequency power being reflected. But the LDMOS field effect transistors mentioned above are mainly insensitive to the reflection of a part of their output signal.

The generation of interference arcs is primarily triggered in the presence of high field strengths by electron field emissions in the resonator. Field emissions of electrons from metal surfaces occur particularly on microscopic peaks in the metal surface of the resonator. The field emission stream grows exponentially with the field strength in the resonator. The field emission stream hitting the resonator wall located opposite the field emitter leads to the deterioration described above in the vacuum and thereby creates the preconditions for a gas discharge, that when combined with the growing emission stream and increasing pressure can create arcing (e.g. an interference arc). Given the low resistance of the plasma in the arc all the energy of the resonator discharges very quickly. The breakdown of the field generates an interference signal of duration Δt, which returns to the HF amplifier via the connection between the resonator and the HF power circuit.

The interference signals generated in this way are particularly dangerous, on the one hand because of their random phasing compared to the phase of the input current supplied by the amplifier and on the other hand because of their unpredictable voltage peaks that can lead to power transistors being destroyed.

A very short signal that is created by the collapse of a field in the resonator is not a harmonic signal. It is a wave packet that meets the condition Δv·Δt≧1, where v is the frequency of the partial waves in the wave packet. A more accurate name would appear to be an electromagnetic pulse, or just pulse for the wave packet that is created by a sudden collapse of the electromagnetic field in the accelerator resonator. If we use v₁ to identify the upper frequency at which the amplitude of the pulse has fallen to around half of its maximum value, and v₂ for the lower frequency, at which the amplitude of the pulse has fallen to around half of its maximum value, then Δv is the difference between these two values, or the width of the frequency interval. The equals sign in the above condition (Δv·Δt≧1) is correct if the pulse is a square wave pulse and all the partial waves have the same amplitude. This is not the case for a pulse generated by the collapse of a field. The description of this event as a pulse that is reflected by the accelerator resonator to the amplifier, is imprecise, as it is not a reflection of the signal sent by the amplifier, but a spontaneous emission from the accelerator resonator. So the shorter the duration Δt of the collapse, the longer the frequency interval Δv. So partial waves arise, whose frequencies may be both higher and lower than the resonant frequency of the resonator.

It is feasible to protect power transistors from these interference signals by means of a circulator which converts a high frequency signal created by a load into a load resistance. Circulators use the Faraday effect of reversing the polarisation of a wave when it passes through ferrite magnets. The reversal of polarity is determined by the product of the length of the wave path in the ferrite, the size of the magnetic field and the value of the Verdet constant. At frequencies below 300 MHz the Verdet constant is increasingly affected by temperature as the frequency is lower. Therefore circulators, in particular in the lower HF range, need to be equipped with temperature regulators.

HF semi-conductor amplifiers for the lower HF range are therefore extremely difficult to build and very expensive.

It is inter alia an object of the present invention to overcome the problems described above.

This object is achieved by a circuit arrangement according to Claim 1, an apparatus according to Claim 8, an apparatus according to Claim 11, an apparatus according to Claim 12, a system according to Claim 19, a use according to Claim 20, a use according to Claim 21 and a use according to Claim 22. Advantageable embodiments can be seen in the dependent patent claims.

The embodiments according to the invention described here and the exemplary embodiments all have in common, among other things, that they enable the protection of the components of an HF element (e.g. an amplifier unit of an HF amplifier, in particular of a VHF amplifier) at least from interference signals arriving through the output of the HF element.

The circuit arrangement according to the invention comprises a pass-through filter section between a first input and/or output node and a second input and/or output node, wherein a pass-through filter with low-pass characteristics or band-pass characteristics is arranged in said pass-through filter section, a first absorption filter section between said first input and/or output node and a third node, wherein a first high-pass filter is arranged in said first absorption filter section, and wherein a first load resistance is arranged at said third node, and a second absorption filter section between said first input and/or output node and a fourth node, wherein a second high-pass filter is arranged in said second absorption filter section, and wherein a second load resistor is arranged at said fourth node.

The circuit arrangement according to the invention comprises, for example, a network of discrete and/or integrated electronic components. The first input and/or output node, the second input and/or output node, the third node and the fourth node are, for example, separate network nodes of a network of the circuit arrangement according to the invention. The first input and/or output node and the second input and/or output node are, for example, implemented as terminal clamps. The may serve, for example as the entry to and/or exit from the circuit.

The pass-through filter section should in particular be regarded as being an electrical connection between the first input and/or output node and the second input and/or output node. For example, the pass-through filter section is the only electrical connection between the first input and/or output node and the second input and/or output node.

The first absorption filter section (and also the second absorption filter section) should therefore in particular be regarded as being an electrical connection between the second input and/or output node (or the first input and/or output node) and the third node (or the fourth node). For example, the first absorption filter section (or the second absorption filter section) is the only electrical connection between the second input and/or output node (or the first input and/or output node) and the third node (or the fourth node).

In the pass-through filter section there may be arranged a pass-through filter with low-pass characteristic, i.e. a low-pass filter or means for low-pass filtering of a signal. This enables, for example, low-pass filtering of a signal transmitted along the pass-through filter section (i.e. between the first input and/or output node or the second input and/or output node to the other input and/or output node). In particular, this can reject or attenuate the transmission of (undesirable) higher frequency signal portions (i.e. in particular signal portions with frequencies above the pass-through range of the pass-through filter, e.g. corresponding interference portions of an interference signal from a load) along the pass-through filter section, at least significantly.

Alternatively, a pass-through filter with band-pass characteristics, i.e. a band-pass filter or means for band-pass filtering of a signal, may be arranged in the pass-through filter section. This, for example, enables band-pass filtering of a signal transmitted along the pass-through filter section (i.e. between the first input and/or output node or the second input and/or output node to the other input and/or output node). In particular, this can reject or attenuate the transmission of (undesirable) higher frequency signal portions (i.e. in particular signal portions with frequencies above and below the pass-through range of the pass-through filter, e.g. corresponding interference portions of an interference signal from a load) along the pass-through filter section, at least significantly. A pass-through filter with band-pass characteristics may, for example, be formed from the serial insertion of a low-pass filter and a high-pass filter.

In the first absorption filter section there is a first high-pass filter and in the second absorption filter section there is a second high-pass filter, i.e. means for high-pass filtering of a signal, arranged. This enables, for example, high-pass filtering of a signal transmitted along the first absorption filter section (i.e. between the second input and/or output node and the third node) or the second absorption filter section (i.e. between the first input and/or output node and the fourth node). In particular, this can reject or attenuate the transmission of low frequency signal portions (i.e. in particular signal portions with frequencies below the pass-through range of the high-pass filter) along the absorption filter section, at least significantly. The first and second high-pass filters are different component groups. They may, for example, have the same or different filter characteristics. For example the first and second high-pass filters may be constructed identically. But it may also be envisaged that they are constructed differently.

Both the first and the second absorption filter section terminate in a load resistor arranged at the third or the fourth node. The first and second load resistor provide, for example, the fullest possible absorption of a signal transmitted along the first or second absorption filter section, for example in the form of a wave sump.

With this construction, the circuit arrangement according to the invention acts as a diplexer for signals applied at both the first input and/or output node and the second input and/or output node. The circuit arrangement according to the invention is thus referred to as a bidirectional diplexer or bidiplexer, and represents a new type of component. It can be used beneficially to provide circuit protection at the output of an HF component (e.g. an amplifier unit of an HF amplifier, in particular a VHF-amplifier). It is inter alia able to cause the protection of an HF component from harmonics of the output signal reflected back into the output of the HF component, and from higher and potentially lower frequency interference signal portions of an interference signal emitted into the output from a load located at the output, for example from a resonator, in particular from an accelerator resonator of a particle accelerator.

According to the invention it is therefore proposed to insert the circuit arrangement according to the invention between the output of the amplifier unit of an amplifier (e.g. of an HF semiconductor amplifier, in particular of a VHF semi-conductor amplifier) of a particle accelerator and the accelerator resonator of a particle accelerator, to protect the power transistor of the amplifier unit from interference signals from the accelerator resonator.

For example, the output signal of the amplifier unit is applied at the first input and/or output node and the interference signal from the accelerator resonator is applied at the second input and/or output node of the circuit arrangement according to the invention. The circuit arrangement according to the invention enables in this example at least doubling the protection of the power transistor for the amplifier unit: in the second load resistor, the harmonics of the output signal of the amplifier unit are absorbed at least for the main part, so that any reflection of the harmonics towards the amplifier unit is substantially avoided, and in the first load resistor the higher frequency interference signal portions of the interference signal from the accelerator resonator are absorbed at least for the main part, so that these interference signal portions do not reach the amplifier unit, or only attenuated. In addition, the pass-through filter with band-pass characteristics may attenuate the transmission of low frequency interference portions of interference signals from the accelerator resonator.

The output signal from the amplifier unit is not free from harmonics. The power contained in these harmonics is not useful, and in the circuit arrangement according to the invention it can be separated out, at least for the main part, and absorbed by a load resistor (e.g. the second load resistor). This power cannot then be reflected back onto the power transistor, allowing a damaging increase in heat in the junction of the power transformer for the amplifier unit to be avoided.

As explained above, in the accelerator resonator of a particle accelerator, free electron streams may cause interference arcs and therefore also interference signals with high voltage amplitudes (e.g. interference signals with voltage amplitudes of 130 V or above, in particular with voltage amplitudes of 150 V or above), that can lead to the destruction of the power transistors in semi-conductor amplifiers. In the circuit arrangement according to the invention, at least the high frequency interference signal portions of these interference signals from the accelerator resonator can not only be reflected and attenuated as with a simple diplexer. Rather, these high-frequency interference signal portions are, at least for the main part, diverted to a load resistor (e.g. to the second load resistor) without any reflections, and are absorbed there.

The threat to the amplifier arising from these undesirable operating conditions is strongly reduced by implementation of the circuit arrangement according to the invention. The circuit arrangement according to the invention operates as a power divider for the interference signals from the accelerator resonator. The absorption of the high-frequency interference signal portions of the interference signals from the accelerator resonator becomes more effective as the frequency of the interference signal rises higher above that of the fundamental frequency of the output signal of the amplifier unit.

The benefit of the bidiplexer according to the invention (i.e. the circuit arrangement according to the invention) consists in particular of the fact that the harmonics generated by the amplifier as well as any power emitted by the resonator or interference signal portions of interference signals with high voltage amplitudes emitted by the resonator are all attenuated.

For example, the pass-through filter and the second high-pass filter are configured in such a way that the fundamental frequency of the output signal of the amplifier unit is transmitted at least for the main part along the pass-through filter section, while harmonics (with frequencies which are a multiple of the frequency of the fundamental wave) of the output signal of the amplifier unit (e.g. harmonics with a higher frequency than the fundamental frequency of the output signal of the amplifier unit) are transmitted at least for the main part along the second absorption filter section, and then absorbed in the second load resistor, at least for the main part. In addition, the first high-pass filter is, for example, configured in such a way that the higher-frequency interference signal portions of the interference signal from the accelerator resonator (e.g. the interference signal portions of the interference signal with a higher frequency than the fundamental frequency of the output signal of the amplifier unit) at least for the main part are transmitted along the first absorption filter section and then absorbed in the first load resistor at least for the main part, but no transmission occurs, or at least not for the main part, of the fundamental frequency of the output signal of the amplifier unit along the first absorption filter section. The transmission of a signal or of a signal portion at least for the main part along a section should be understood specifically to mean that at least 90%, and preferably at least 95%, of the power of the signal or the signal portion should be transmitted along this section. A transmission of 90% of the power of a signal along a section corresponds to attenuation of the signal during the transmission of approx. −0.46 dB.

The circuit arrangement according to the invention is implementable using only passive electronic components, in particular no expensive (active) temperature control is needed. It can therefore be produced simply and at low cost. The circuit arrangement according to the invention is therefore particularly beneficial for use in the HF semiconductor amplifiers of a particle accelerator (in particular in VHF semiconductor amplifiers in a particle accelerator) instead of the circulators used to date.

According to an exemplary embodiment of the circuit arrangement according to the invention, the pass-through filter and/or the first high-pass filter and/or the second high-pass filter are second order or higher filters, preferably third order filters. For example, these filters may be implemented as active and/or passive filters, for example as Butterworth filters, Sallen-Key filters, elliptical filters or Tschebyscheff filters. By using second or higher order filters, better attenuation of undesirable signal portions beyond the cutoff frequencies is achieved.

According to an exemplary embodiment of the circuit arrangement according to the invention, the pass-through filter and/or the first high-pass filter and/or the second high-pass filter are passive filters.

According to an exemplary embodiment of the circuit arrangement according to the invention, the pass-through filter, in particular the pass-through filter with low-pass characteristics, is formed by at least two inductors and at least one capacitor in a T-network. For example, the inductance of each of the minimum two inductors in the pass-through filter can amount to 90 nH and the capacitance of the at least one capacitor in the pass-through filter can be at least 43 pF. Alternatively, it may for example be envisaged that the pass-through filter, in particular the pass-through filter with low-pass characteristics, is formed by at least two capacitors and at least one inductor in a PI-network. In addition, for example, further components or groups of components may also be used to form the pass-through filter.

According to an exemplary embodiment of the circuit arrangement according to the invention, the first and/or second high-pass filters are respectively formed by at least two capacitors and at least one inductor in a T-network. For example, the inductance of the at least one inductor in the first and second high-pass filters may be 36 nH, the capacitance of one of the at least two capacitors in the first and second high-pass filters may be 16 pF, and the capacitance of the other of the at least two capacitors in the first and second high-pass filters may be 22 pF. Alternatively, it may for example be envisaged that the first and/or second high-pass filters are respectively formed by at least two inductors and at least one capacitor in a PI-network. In addition, for example, further components or groups of components may be used to form the first or second high-pass filters, such as for example an additional inductor inserted in series with the T-network consisting of the at least two capacitors and the at least one inductor.

According to an exemplary embodiment of the circuit arrangement according to the invention, the pass-through filter with low-pass characteristics is configured such that its cutoff frequency is larger than a predetermined fundamental frequency, (also referred to as the first harmonic, f) of a fundamental wave and less than the frequency (2f) of the second harmonic of the fundamental wave, and the first and second high-pass filters are respectively configured such that their respective cutoff frequency is higher than the predetermined fundamental frequency (f) of the fundamental wave and lower than the frequency (2f) of the second harmonic of the fundamental wave.

The cutoff frequency should in particular be understood to be the frequency at which the power of the output signal of a filter falls to half of the power of the input signal of the filter, so an attenuation of −3 dB has occurred. The cutoff frequency of the pass-through filter with low-pass characteristics is, for example, the upper limit of the pass-through range of the pass-through filter with low-pass characteristics. The cutoff frequency of the pass-through filter with low-pass characteristics is, for example, 150%, preferably 125%, more preferably 110% of the fundamental frequency of the fundamental wave. The predetermined fundamental frequency of the fundamental wave preferably lies within the pass-through range of the pass-through filter with low-pass characteristics. This means that high-frequency interference portions of an interference signal (i.e. in particular those interference portions of an interference signal that have frequencies above the pass-through range of a pass-through filter with low-pass characteristics, e.g. interference portions of an interference signal with frequencies 150% or higher, preferably 125% or higher and more preferably 110% or higher than the fundamental frequency of the fundamental wave) are not transmitted at all or only transmitted strongly attenuated from the first input and/or output node or the second input and/or output node to the other input and/or output node.

When using the circuit arrangement according to the invention in an HF amplifier of a particle accelerator, the predetermined fundamental frequency for example corresponds to the fundamental frequency of the fundamental wave of the output signal of the amplifier unit of the HF amplifier (e.g. 72 MHz). This makes it possible for the fundamental wave of the output signal of the amplifier unit to be transmitted almost without attenuation from the first input and/or output node or the second input and/or output node to the other input and/or output node. The harmonics of the output signal (i.e. the second and higher harmonics of the fundamental wave of the output signal), and the higher frequency interference signal portions of the interference signal of the accelerator resonator (i.e. in particular interference signal portions with frequencies above the pass-through range of the pass-through filter with low-pass characteristics, e.g. interference signal portions of the interference signal with frequencies of 150% or higher, preferably 125% or higher, and more preferably 110% or higher of the fundamental frequency of the fundamental wave) are only transmitted in a strongly suppressed form from the first input and/or output node or the second input and/or output node and to the other input and/or output node. Instead, the harmonics of the output signal and the higher frequency interference signal portions of the interference signal of the accelerator resonator are transmitted almost without attenuation along the first or second absorption filter sections and absorbed by the first or second load resistor as fully as possible, so that these signals pass only strongly attenuated through the circuit arrangement according to the invention.

For example, the pass-through filter and the first and second high-pass filters may be configured such that the fundamental wave of the output signal of the amplifier unit, when transmitted from the first input and/or output node or the second input and/or output node to the other input and/or output node, is only attenuated by −0.5 dB, whereas the second harmonic of the fundamental wave of the output signal of the amplifier unit is attenuated by at least −10 dB and the third harmonic of the fundamental wave of the output signal of the amplifier unit is attenuated by at least −25 dB. In addition, the pass-through filter and the first and second high-pass filters may be configured such that the signal reflected from the circuit arrangement according to the invention is attenuated by at least −20 dB.

According to an exemplary embodiment of the circuit arrangement according to the invention, the pass-through filter with band-pass characteristics is configured such that its lower cutoff frequency is lower than a predetermined fundamental frequency, (also called the first harmonic, f) of a fundamental wave and its upper cutoff frequency is higher than a predetermined fundamental frequency (f) of a fundamental wave and lower than the frequency of the second harmonic (2f) of the fundamental wave, and the first and second high-pass filters are respectively configured such that their respective cutoff frequency is higher than the predetermined fundamental frequency (f) of the fundamental wave and lower than the frequency (2f) of the second harmonic of the fundamental frequency.

The upper cutoff frequency of the pass-through filter with band-pass characteristics is for example, the upper limit of the pass-through range of the pass-through filter with band-pass characteristics and the lower cutoff frequency of the pass-through filter with band-pass characteristics is the lower limit of the pass-through range of the pass-through filter with band-pass characteristics. The predetermined fundamental frequency of the fundamental wave lies preferably within the pass-through range of the pass-through filter with band-pass characteristics. The upper cutoff frequency of the pass-through filter with band-pass characteristics is for example 150%, preferably 120%, more preferably 110% of the fundamental frequency of the fundamental wave. The lower cutoff frequency of the pass-through filter with band-pass characteristics is for example 50%, preferably 75%, more preferably 90% of the fundamental frequency of the fundamental wave. As mentioned above, the predetermined fundamental frequency, when using the circuit arrangement according to the invention in an HF amplifier, corresponds, for example, to the fundamental frequency of the fundamental wave of the output signal of the amplifier unit (e.g. 72 MHz).

This means that higher frequency and lower frequency interference signal portions of the interference signal (i.e. in particular interference signal portions with frequencies above and below the pass-through range of the pass-through filter with band-pass characteristics, e.g. interference signal portions of the interference signal with frequencies 150% or higher, preferably 125% or higher, more preferably 110% or higher of the fundamental frequency of the fundamental wave and those 50% or lower, preferably 75% or lower, more preferably 90% or lower of the fundamental frequency of the fundamental wave) are not transmitted at all or only transmitted strongly attenuated from the first input and/or output node or the second input and/or output node to the other input and/or output node.

According to an exemplary embodiment of the circuit arrangement according to the invention, the first and second load resistors each match the wave resistance, in particular the wave resistance of the used conductor, in particular the wave resistance of the used conductor at the fundamental frequency of the fundamental wave of the output signal of the amplifier unit. Typical conductors, for example, have a wave impedance of 50Ω or 75Ω. By using the wave impedance as load resistance a reflection of the signals or of signal portions transmitted along the first or second absorption filter sections is prevented.

A first apparatus according to the invention, in particular an inventive amplifier module for an amplifier (e.g. for an HF amplifier, in particular for a VHF amplifier), comprises one or more amplifier branches, wherein each amplifier branch comprises the circuit arrangement according to the invention and an amplifier unit, in particular a semiconductor amplifier unit.

According to an exemplary embodiment of the first apparatus according to the invention, the output of the amplifier unit is arranged at one of the input and/or output nodes of the circuit arrangement according to the invention. In particular, the circuit arrangement according to the invention can be inserted between the amplifier unit and an output of the amplifier branch. This may cause protection for the amplifier unit at least from higher frequency (or potentially lower frequency) interference signal portions of an interference signal travelling from the output of the amplifier branch or from an output of the apparatus toward the amplifier unit. These may, for example, be interference signals with a high voltage amplitude emitted by a load (e.g. an accelerator resonator) (e.g. interference signals with voltage amplitudes of 130 V or higher, in particular with voltage amplitudes of 150 V or higher), that are at least partially attenuated and/or absorbed by the circuit arrangement according to the invention. In addition, the circuit arrangement according to the invention may prevent reflection of the harmonics of the output signal of the amplifier unit back to the amplifier unit.

According to an exemplary embodiment of the first apparatus according to the invention, each of the output signals of two or more amplifier branches of the one or more amplifier branches are combined by a signal combiner, in particular a 90° hybrid combiner, to a single signal. The signal combiner is, for example, a signal combiner of a first level of signal combiners. The signal is, for example, an output signal of the signal combiner, for example an output signal of a first level of signal combiners. But equally, the signal may also be an input signal of a second signal combiner and/or other components and/or the output signal of the apparatus. The output signals of two or more first level signal combiners may, for example, each be combined by a second level signal combiner, in particular a 90° hybrid combiner, to a single signal (for example, an output signal of the second level of signal combiners).

For example, the signal combiner or signal combiners may be inserted between the amplifier branch and an output of the apparatus.

Examples of a signal combiner are, as described below, a Wilkinson combiner and a hybrid combiner, in particular a 90° hybrid combiner.

A second apparatus according to the invention, in particular an inventive amplifier module for an amplifier (e.g. for an HF amplifier, in particular for an VHF amplifier), comprises one or more amplifier branches, wherein each amplifier branch comprises an amplifier unit, wherein each of the output signals of two or more amplifier branches of the one or more amplifier branches are combined by a signal combiner, in particular a 90° hybrid combiner, to a single signal. The signal combiner is, for example, a signal combiner of a first level of signal combiners. The signal is, for example, an output signal of the signal combiner, for example an output signal of a first level of signal combiners. But equally, the signal may also be an input signal for a second signal combiner and/or other components and/or the output signal of the apparatus. The output signals of two or more first level signal combiners may, for example, each be combined by a second level signal combiner, in particular a 90° hybrid combiner, to a single signal (for example, an output signal of the second level of signal combiners).

For example, the signal combiner or signal combiners can be inserted between the amplifier branches and an output of the apparatus.

Examples of a signal combiner are a Wilkinson combiner and a hybrid combiner, in particular a 90° hybrid combiner.

90° hybrid combiners provide an excellent match to the common output port, also in the case of tuning to individual semiconductor amplifier units or amplifier branches for maximum output power, for maximum efficiency and maximum amplification. In addition, 90° hybrid combiners have a very minor reduction in the insulation between individual semiconductor amplifiers or amplifier branches in the event of a mismatched load at the common port, as well as greater immunity for the semiconductor amplifier units or amplifier branches due to their combination in a 90° hybrid combiner than is the case of a stand-alone semiconductor amplifier or amplifier branch.

Wilkinson combiners with an output port set to a load of 50Ω, require a matching to the semiconductor amplifier units or amplifier branches to 50Ω, otherwise a Wilkinson combination is ineffective. But a change to this matching applies if the semiconductor amplifier units or amplifier branches are run under different operational conditions. In addition, using Wilkinson combiners can lead to a reduction in the insulation between the input ports, if there is mismatch of the output ports. An advantage of the Wilkinson combiner is its symmetrical construction and the simplicity of its design.

In particular due to the capacitance pass-through 90° hybrid combiners have narrower bandwidth than Wilkinson combiners. They also have a more band-pass type transmission function than Wilkinson combiners. By inserting correctly matched 90° hybrid combiners between the amplifier units and the output, protection from higher and lower frequency interference signal portions of an interference signal travelling from the output of the apparatus towards the amplifier unit may thus be caused. This may, for example, be interference signals with high voltage amplitudes (e.g. interference signals with voltage amplitudes of 130 V or greater, in particular with voltage amplitudes of 150 V or greater) emitted by a load (e.g. an accelerator resonator) to the output that are at least in part be attenuated by the band-pass type transmission function of the 90° hybrid combiner.

An amplifier module is, for example, the smallest modular and/or replaceable unit of an amplifier, for example an amplifier according to the invention.

An amplifier unit comprises, for example, at least four amplifier branches and at least two levels of combiners.

An amplifier according to the invention, for example an HF amplifier according to the invention, in particular a VHF amplifier according to the invention, comprises one or more of the first and/or second apparatus according to the invention.

A third apparatus according to the invention, in particular an amplifier according to the invention (e.g. an HF amplifier according to the invention, in particular a VHF amplifier according to the invention), comprises one or more amplifier branches, wherein each amplifier branch comprises one amplifier unit, an output, and one or more protective filters, wherein the one or more protective filters are inserted between the amplifier units of the amplifier branches and the output.

The output is the output of the apparatus, for example the amplifier output of an amplifier according to the invention.

The amplifier unit of an amplifier branch of the third apparatus according to the invention (and also of the first and second apparatus according to the invention) comprises, for example, a transistor circuit arrangement with at least one power transistor, e.g. a MOSFET (Metal Oxide Semiconductor Field Effect Transistor) transistor and/or an LDMOS (Laterally Diffused Metal Oxide Semiconductor) transistor. An example of a suitable LDMOS transistor is the BLF 574 transistor from NXP. Preferably the transistor circuit is configured as a push-pull transistor amplifier circuit or as a push-pull transistor amplifier circuit arrangement. A semiconductor amplifier unit is characterised by the fact that at least the power transistor or power transistors, and preferably the whole transistor circuit arrangement, is formed by semiconductor techniques (e.g. as an integrated circuit). The amplifier unit may, for example, instead of the semiconductor amplifier unit, use other forms of implementation with other constructions and/or with separate components.

The fundamental frequency of the fundamental wave of the output signal of the amplifier unit lies for example in the HF range, for example in the VHF range, preferably between 30 MHz and 150 MHz, more preferably between 30 MHz and 100 MHz. For example, the fundamental frequency of the fundamental wave of the output signal of the amplifier unit is 72 MHz.

Between the outputs of the amplifier units of the amplifier branches and the output, there is preferably an electrical connection, for example via the protective filter and potentially one or more levels of signal combiners and/or further components.

For example, the protective filters are inserted between the amplifier units of the amplifier branches and the output such that the protective filters filter signals travelling from the output to the amplifier units (i.e. attenuate at least signal portions of these signals). This causes protection of the amplifier units at least against interference signal portions of an interference signal travelling from the output towards the amplifier unit, in particular interference signal portions of an interference signal with frequencies outside the pass-through range of the protective filter. These may, for example, be interference signals with a high voltage amplitude emitted by a load (e.g. an accelerator resonator) into the output (e.g. interference signals with voltage amplitudes of 130 V or higher, in particular with voltage amplitudes of 150 V or higher), that are at least partially attenuated by the protective filter.

According to an exemplary embodiment of the third apparatus according to the invention, the protective filters are configured as high-pass and/or band-pass filters. The protective filters may accordingly have high-pass characteristics and/or band-pass characteristics. Preferably the protective filters are formed identically. But it may be envisaged that different protective filters are used.

The cutoff frequency of a protective filter configured as a high-pass filter may, for example, be lower than a predetermined fundamental frequency of a fundamental wave. The cutoff frequency of a protective filter configured as a high-pass filter is, for example, 50%, preferably 75%, more preferably 90% of the fundamental frequency of the fundamental wave. The lower cutoff frequency of a protective filter configured as a band-pass filter may for example be lower than the predetermined fundamental frequency of a fundamental wave and the upper cutoff frequency may be higher than a predetermined fundamental frequency of a fundamental wave. The lower cutoff frequency of a protective filter configured as a band-pass filter is, for example, 50%, preferably 75%, more preferably 90% of the fundamental frequency of the fundamental wave. The upper cutoff frequency of a protective filter configured as a band-pass filter is, for example, 150%, preferably 125% and ideally 110% of the fundamental frequency of the fundamental wave. Preferably the fundamental frequency of the fundamental wave lies within the pass-through range of the protective filter. Preferably the predetermined fundamental frequency corresponds to the fundamental frequency of the fundamental wave of the output signal of the amplifier unit (e.g. 72 MHz).

The protective filters are, for example, first order filters, preferably second order or higher filters. For example, these filters can be implemented as active and/or passive filters, for example as Butterworth filters, Sallen-Key filters, elliptical filters or Tschebyscheff filters. By using second or higher order filters, better attenuation of interference signal portions of the interference signal beyond the cutoff frequencies is achieved.

A protective filter, in particular a protective filter configured as a high-pass filter can, for example, be formed by at least two capacitors and one inductor in a T-network. For example, the capacitors have a capacitance of 47.5 pF and the inductor has an inductance of 107 nH, so that the cutoff frequency of the protective filter is approx. 65 MHz (so approx. 87% of 72 MHz). A first order protective filter of this type provides attenuation of approx. −6 dB at 40 MHz, approx. −14 dB at 30 MHz, approx. −25 dB at 20 MHz, approx. −44 dB at 10 MHz and approx. −62 dB at 5 MHz. Alternatively, one could envisage for example, a protective filter configured as a high-pass filter formed by at least two inductors and one capacitor in a PI-network. In addition, other examples of components or groups of components could be configured and added to form the additional high-pass filter. A protective filter configured as a band-pass filter may, for example, be formed by combining a high-pass filter and a low-pass filter in series.

If the protective filters are configured as high-pass filters, then the protective filters at least protect the amplifier units against low frequency interference signal portions of an interference signal travelling from the output towards the amplifier unit (i.e. in particular interference signal portions of an interference signal with frequencies below the pass-through range of the protective filter, e.g. interference signal portions of the interference signal with frequencies that are 50% or lower, preferably 75% or lower, more preferably 90% or lower than the fundamental frequency of the fundamental wave). If the protective filters are configured as a band-pass filters, then the protective filters at least protect the amplifier units against lower and higher frequency interference signal portions of an interference signal travelling from the output toward the amplifier unit (i.e. in particular interference signal portions of an interference signal with frequencies below and above the pass-through range of the additional band-pass filter, e.g. interference signal portions of an interference signal with frequencies that are 150% or higher, preferably 125% or higher, more preferably 110% or higher of the fundamental frequency of the fundamental wave, and 50% or lower, preferably 75% or lower, more preferably 90% or lower than the fundamental frequency of the fundamental wave). These may, for example, be interference signals emitted by a load (e.g. an accelerator resonator) into the output.

According to an exemplary embodiment of the third apparatus according to the invention, each amplifier branch also comprises a circuit arrangement according to the invention or a diplexer.

For example, a circuit arrangement according to the invention may be inserted in each amplifier branch between the amplifier unit and an output of the amplifier branch. For example, the output of the amplifier unit is electrically connected to one of the input and/or output nodes of the circuit arrangement according to the invention, and the other input and/or output node of the circuit arrangement according to the invention is connected to the output of the amplifier branch or the output of the apparatus. In particular, the circuit arrangement according to the invention can be inserted between the amplifier unit and the output of amplifier branch or the output of the apparatus. This means, among other things, that additional protection can be provided for the amplifier unit against higher frequency (or potentially lower frequency) interference signal portions of an interference signal travelling from the output towards the amplifier unit. In addition, the circuit arrangement according to the invention may prevent reflection of the harmonics of the output signal from the amplifier unit back to the amplifier unit.

For example, a diplexer can be inserted in each amplifier branch between the amplifier unit and an output of the amplifier branch.

A diplexer is generally a multiplexer which connects one input to two outputs. It is a crossover unit, and is used to decouple two frequency ranges. For example, the diplexer in the amplifier according to the invention can be used to separate a fundamental wave from the harmonics to the fundamental wave (e.g. the second harmonic of the fundamental wave and the higher harmonics to the fundamental wave). For example, the output of the amplifier unit is connected electrically to the input of the diplexer and the output of the diplexer to the output of the amplifier branch or to the output of the amplifier. In particular, the diplexer can be inserted between the amplifier unit and an output from the amplifier branch or the amplifier output.

Preferably the diplexer in the third apparatus according to the invention may comprise the pass-through filter section and the second absorption filter section with the second load resistor according to the invention circuit, so that it is differentiated from the circuit arrangement according to the invention and the above exemplary embodiments by the lack of the first absorption filter section with the first load resistor. In this example, the output of the amplifier unit may be electrically connected to the first input and/or output node of the diplexer, and the second input and/or output node of the diplexer to the output of the amplifier branch or the output of the apparatus.

As described above, the pass-through filter of the pass-through filter section is for example configured such that the fundamental wave of the output signal from the amplifier unit is transmitted, at least for the main part, along the pass-through filter section, and the second high-pass filter in the second absorption filter section is configured such that the harmonics of the output signal from the amplifier unit (e.g. the harmonics with a higher frequency than the fundamental frequency of the fundamental wave of the output signal from the amplifier unit) are transmitted for the main part along the second absorption filter section and then are absorbed in the second load resistor, at least for the main part. According to this, the diplexer can prevent, among other things, a reflection of harmonics from the output signal of the amplifier unit back to the amplifier unit.

According to an exemplary embodiment for the third apparatus according to the invention, the third apparatus according to the invention further comprises a first level of signal combiners, wherein the first level of signal combiners comprises one or more signal combiners, in particular one or more 90° hybrid combiners, and the signal combiners for the first level of signal combiners are inserted between the amplifier branches and the amplifier output. For example, the signal combiners for the first level of signal combiners are inserted between the amplifier branches and the amplifier output such that each of the output signals of two or more amplifier branches of the one or more amplifier branches are combined by a first level signal combiner, in particular a 90° hybrid combiner, to a single signal. The signal may, for example, be an output of the signal combiner, for example an output signal of a first level of signal combiners. But equally, the signal may be an input signal of a second signal combiner and/or other components and/or the output signal of the apparatus. The output signals of two or more first level signal combiners may, for example, each be combined by a second level signal combiner, in particular by a 90° hybrid combiner, to a single signal (for example, an output signal of the second level signal combiners).

Examples of a signal combiner are, as described above, a Wilkinson combiner and a hybrid combiner, in particular a 90° hybrid combiner.

For example, the third apparatus according to the invention (and also the first and second apparatus according to the invention) may comprise several levels of such combiners, preferably at least two levels of combiners, more preferably at least three levels of combiners. This is useful, for example, to combine all the output signals (or output powers) of several amplifier branches to a single output signal (or a single output power) of the apparatus. An amplifier unit of an amplifier branch is then, for example, electrically connected via the protective filter and the levels of combiners to the output.

For example, the third apparatus according to the invention (and also the first and second apparatus according to the invention) may comprise at least two levels of combiners (e.g. of hybrid combiners), wherein the first level combiners each combine the output signals of at least two amplifier branches to an output signal of the first level, and the second level combiners each combine at least two output signals of the first level to an output signal of the second level.

An amplifier module of an amplifier according to the invention comprises, for example, at least four amplifier branches and at least two levels of combiners.

The input signal to the third apparatus according to the invention (and also to the first and second apparatus according to the invention) may, for example, be divided by a signal splitter between several amplifier branches. Examples such a splitter are a Wilkinson splitter and a hybrid splitter, in particular a 90° hybrid splitter. For example, the third apparatus according to the invention (and also the first and second apparatus according to the invention) may comprise multiple levels of such splitters, preferably at least two levels of splitters, more preferably at least three levels of splitters. In particular, the number of splitter levels (or the number of splitters) may match the number of levels of combiners (or the number of combiners).

An amplifier module of an amplifier according to the invention comprises, for example, at least two levels of splitters, at least four amplifier branches and at least two levels of combiners.

According to an exemplary embodiment for the third apparatus according to the invention, the protective filters are inserted between the first level of signal combiners and the output. This reduces the number of protective filters that are needed.

For example, the protective filters may be inserted between the first level of signal combiners and a second level of signal combiners. In order to require only one single protective filter for all amplifier units, the protective filter may be inserted between the last level of combiners and the output (i.e. arranged at the output).

According to an exemplary embodiment for the third apparatus according to the invention, the third apparatus according to the invention only comprises one protective filter, and this protective filter is arranged at the amplifier output.

According to an exemplary embodiment of the third apparatus according to the invention, each amplifier branch also comprises a protective filter. This is, for example, advantageous to keep the load on each protective filter as low as possible.

The system according to the invention comprises one of the apparatus according to the invention and a particle accelerator, wherein the accelerator resonator of the particle accelerator is electrically connected to the apparatus output.

A use according to the invention is the use of one or more protective filters in one amplifier for a particle accelerator to protect the amplifier units of the amplifier against interference signals emitted by the accelerator resonator and travelling into the amplifier output of the amplifier. For example, the protective filters are inserted between the amplifier units and the amplifier output or the accelerator resonator. The protective filters are, for example, high-pass filters and/or band-pass filters. The cutoff frequency of a protective filter configured as a high-pass filter, as explained above, is for example 50%, preferably 75%, more preferably 90% of the fundamental frequency of the fundamental wave. The lower cutoff frequency of a protective filter configured as a band-pass filter is, for example, 50%, preferably 75%, more preferably 90% of the fundamental frequency of the fundamental wave. The upper cutoff frequency of a protective filter configured as a band-pass filter is, for example, 150%, preferably 125% , more preferably 110% of the fundamental frequency of the fundamental wave. The amplifier corresponds, for example, to an apparatus according to the invention. The use of the protective filter inter-alia serves for attenuating the (lower frequency and/or higher frequency) interference signal portions of an interference signal travelling into the amplifier output of the accelerator resonator of the particle accelerator (e.g. an interference signal with voltage amplitudes of 130 V or greater, in particular with voltage amplitudes of 150 V or greater).

A further use according to the invention is the use of one or more signal combiners in an amplifier for a particle accelerator to protect the amplifier against interference signals emitted by the particle accelerator and travelling into the amplifier output of the amplifier. For example, one or more signal combiners are inserted between the amplifier units and the amplifier output or the accelerator resonator. The amplifier corresponds, for example, to an apparatus according to the invention. The use of the signal combiners inter-alia serves for attenuating the (lower frequency and/or higher frequency) interference signal portions of an interference signal travelling into the amplifier output of the accelerator resonator of the particle accelerator (e.g. an interference signal with voltage amplitudes of 130 V or greater, in particular with voltage amplitudes of 150 V or greater).

A further use according to the invention is the use of one or more circuit arrangements according to the invention in an amplifier for a particle accelerator to protect the amplifier units of the amplifier against interference signals emitted by the accelerator resonator and travelling into the amplifier output of the amplifier. For example, one or more circuit arrangements according to the invention are inserted between the amplifier units and the amplifier output or the accelerator resonator. The amplifier corresponds for example to an apparatus according to the invention. The use of the circuit arrangement according to the invention inter-alia serves for attenuating the (lower frequency and/or higher frequency) interference signal portions of an interference signal travelling into the amplifier output of the accelerator resonator of the particle accelerator (e.g. an interference signal with voltage amplitudes of 130 V or greater, in particular with voltage amplitudes of 150 V or greater). In addition, the use of the circuit arrangement according to the invention servers for preventing the reflection of harmonics from the output signal of the amplifier unit back to the amplifier unit.

The example embodiments of the present invention described in this application should be disclosed in any combination with each other.

Other advantageous example embodiments of the invention can be found in the following detailed descriptions of some example embodiments, in particular in combination with the drawings.

The drawings attached to the application should, however, only be used for the purposes of clarification, not to determine the scope of protection of the invention. The attached drawings are not drawn to scale and are only intended to reflect the general concept of the present invention in the form of examples. In particular, the features that are comprised in the drawings are not to be considered as necessary components of the present invention.

### SHORT DESCRIPTION OF THE DRAWINGS

In the figures, it is shown:

FIG. 1 shows a block diagram of an example of a system according to the invention with an HF amplifier and a particle accelerator.

FIG. 2a shows a schematic representation of an example of an amplifier module of an HF amplifier according to the invention.

FIG. 2b shows a schematic representation of an example of an amplifier module of an HF amplifier according to the invention.

FIG. 2c shows a schematic representation of an example of an amplifier module of an HF amplifier according to the invention.

FIG. 2d shows a schematic representation of an example of an amplifier module of an HF amplifier according to the invention.

FIG. 2e shows a schematic representation of an example of an amplifier branch of an HF amplifier according to the invention.

FIG. 2f shows a schematic representation of an example of an amplifier branch of an HF amplifier according to the invention.

FIG. 3 shows a circuit schematic for a classic diplexer.

FIG. 4 shows a circuit schematic for an example of a circuit arrangement according to the invention or a bidiplexer according to the invention.

FIG. 5 shows two frequency responses for the example of a circuit arrangement according to the invention or a bidiplexer according to the invention shown in FIG. 4.

### DETAILED DESCRIPTION OF SOME EXEMPLARY EMBODIMENTS OF THE PRESENT INVENTION

In the following, the components of an exemplary embodiment of a VHF amplifier according to the invention, according to the first aspect of the invention, referred to in this section as amplifier CRE312B, are explained. Each amplifier branch of this amplifier comprises a circuit arrangement according to the invention, that is referred to each time in the following as a bidirectional diplexer or bidiplexer, and is tagged in the diagrams with the reference number 100. The amplifier CRE312B is optimised for operation at 72 MHz and for the high frequency supply of an accelerator resonator of a particle accelerator. Basically, the present invention is not, however, restricted to the application of this special frequency and this type of usage, but is suitable for use across the whole HF range (approx. 30 MHz to approx. 30 GHz), in particular in the frequency range below 100 MHz. Another potential usage of the invention would be, for example, in radio and television transmission systems.

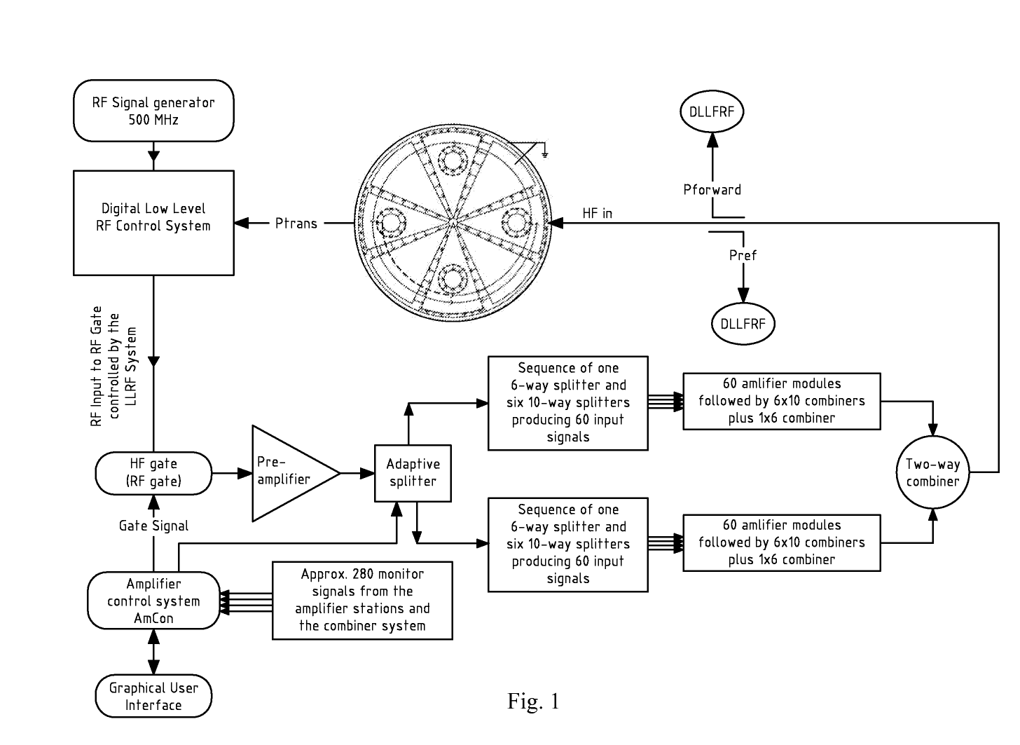

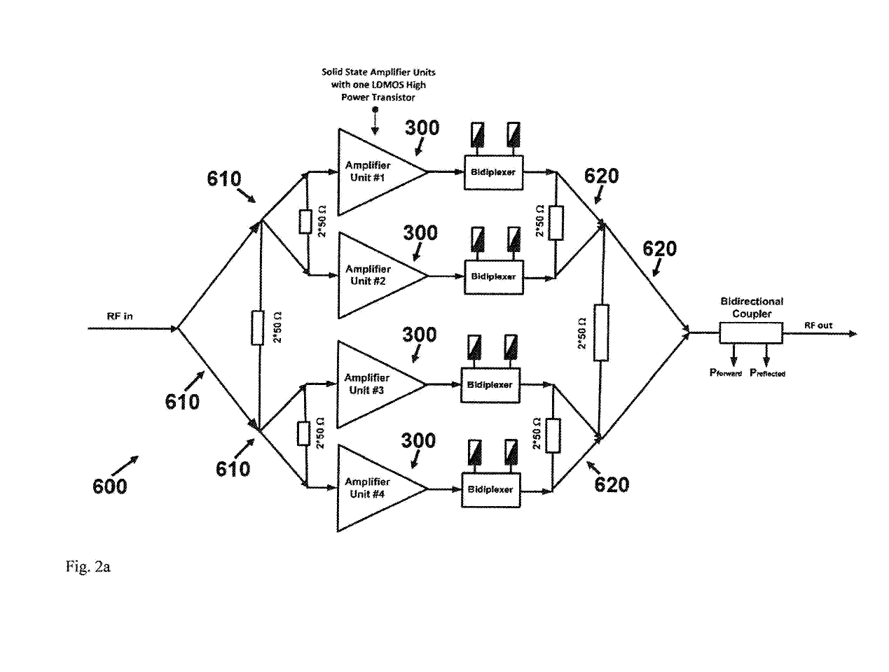

FIG. 1 shows a block diagram of the amplifier CRE312B. The input signal of the VHF amplifier is delivered, when operating with a particle accelerator, by a signal generator that is modulated by the Digital Low Level RF (DLLRF) Control System control and regulating electronic system. The DLLRF electronic control system monitors the phase and amplitude of the acceleration field in the accelerator resonator of the particle accelerator. For the amplifier CRE312B this is the accelerator resonator of a 250 MeV proton cyclotron with sector focussing and an operational frequency of 72 MHz. The level of the amplifier input signal is 0 dBm (1 mW). The path of the signal and its amplification to maximum 150 kW is sketched out in FIG. 1.

The signal from the DLLRF electronic control system first reaches the high frequency gate (HF Gate or RF Gate), it is the first element of the amplifier's entry level. Opening and closing the HF gate is managed by the AmCon control system. The RF gate offers the most rapid option to be able to cut out the output signal from the CRE312B amplifier and so to switch off the beam in the particle accelerator.

The AmCon amplifier control system registers a large number of characteristic metrics, which are provided by the components of the CRE312B amplifier, and it monitors and controls the functions of the CRE312B amplifier.

After passing the HF gate, the input signal is reinforced for further processing in a low noise input amplifier to the necessary level for the following electronic circuits. The input signal then reaches the first amplifier component groups of the CRE312B amplifier. An amplifier component group is defined by a splitter at the entry and a corresponding combiner at the component output.

Signal splitters and signal combiners are necessary component groups in a transistorised VHF high power amplifier. The most performant transistors for the VHF range each deliver output power of between 400 and 800 Watt, depending on the type. If losses in the combiner network are taken into account, up to 500 transistors can be comprised in one high power amplifier. In the CRE312B amplifier, which uses the BLF 574 transistor from NXP, there are 480 transistors. The input signal from the CRE312B amplifier thus needs to be split in several levels a total of 480 times. Conversely, the 480 output signals from the power transistors need to be combined 480 times in several combiner levels. This is done using the sensible approach that each combiner level with N combiners matches a splitter level with N splitters.

The CRE312B amplifier is made up in total of the following amplifier component groups:
amplifier divisions that are made up of amplifier sections
amplifier sections, that are made up of amplifier modules,
amplifier modules, that are made up of two symmetrical semiconductor amplifiers or four
amplifier branches,
symmetrical semiconductor amplifiers, that are made up of two power transistors or two amplifier branches.

The CRE312B amplifier comprises 6 stations where the amplifier component groups are located. The stations each consist of an upper and a lower amplifier section. This are preferably mounted up and down in a standard 19″ electronics rack.

The amplifier division #1 (see FIG. 1) of the CRE312B amplifier consists of the upper amplifier sections of the 6 amplifier stations, and amplifier division #2 (see FIG. 1) consists of the 6 lower amplifier sections of the amplifier stations Each section is made up of 10 amplifier modules.

An amplifier module is the core electronic component of the CRE312B amplifier. The output signals of the 10 amplifier modules in an amplifier section are combined in a 10×-combiner using a coaxial cable design into a total signal for an amplifier section. Further combiners of graduated power-bearing capacity bring together the signal from the total of 12 10×-combiners.

The amplifier module in the CRE312B amplifier is made up of the following elements:
a 2×-splitter at the input to the amplifier module,
two symmetrical amplifiers (each including a 2×-splitter, two amplifier branches and a 2×-combiner),
a 2×-combiner,
a bidirectional HF power coupler at the output of the amplifier module.

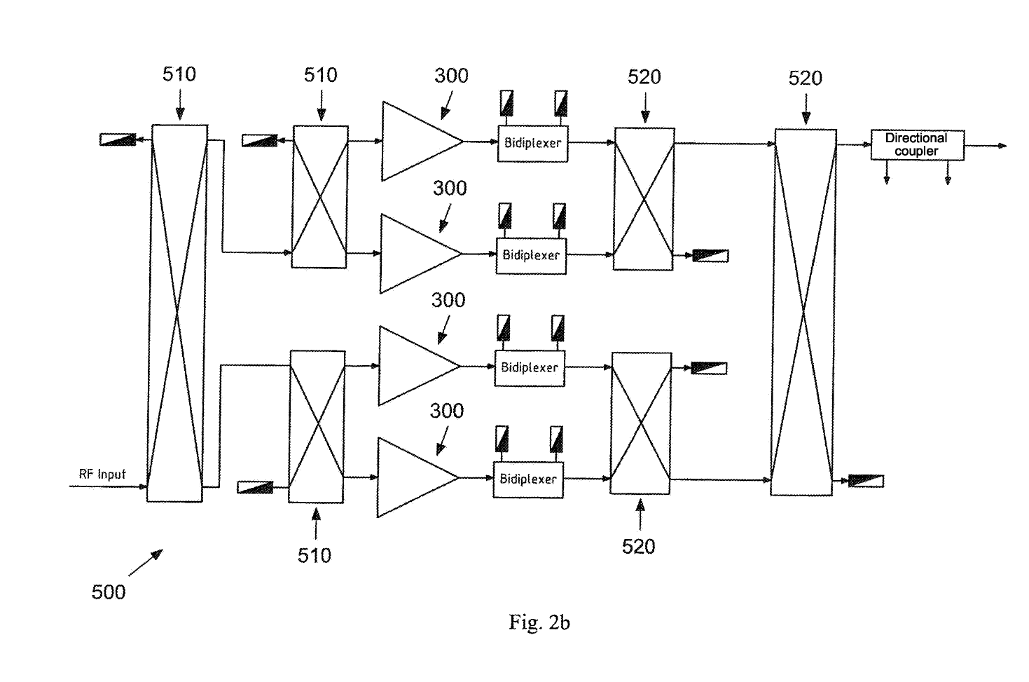

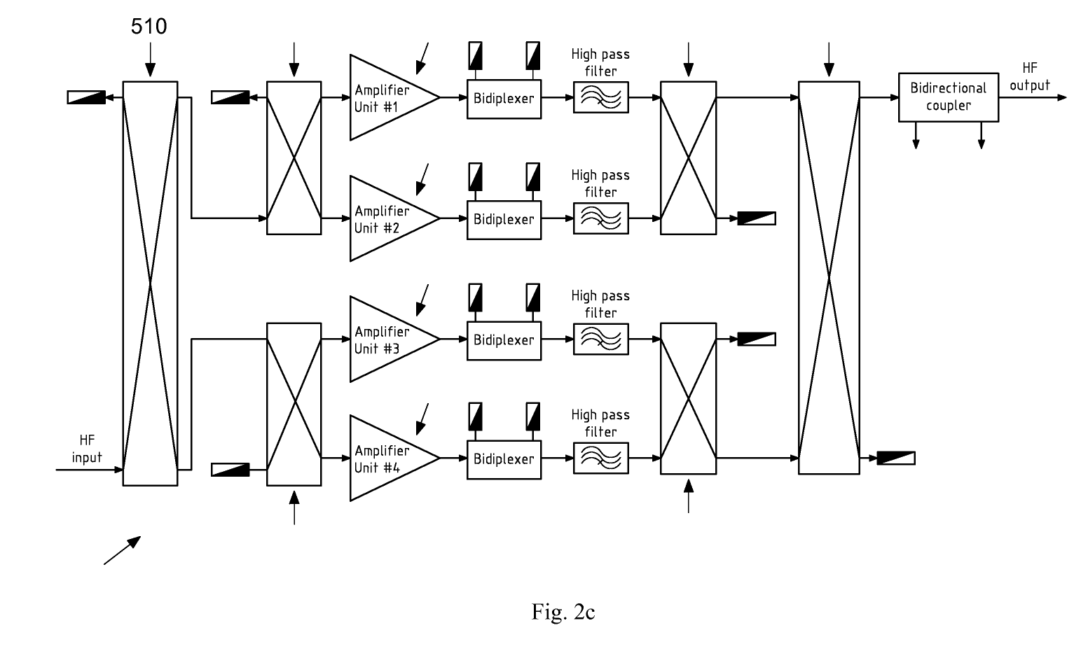

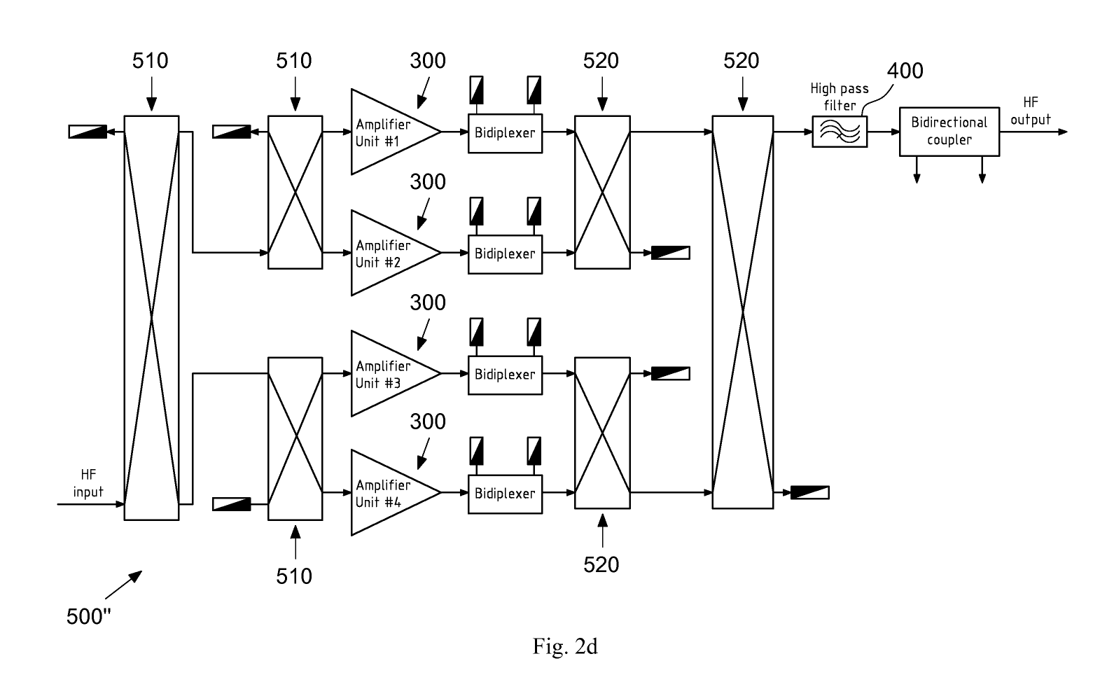

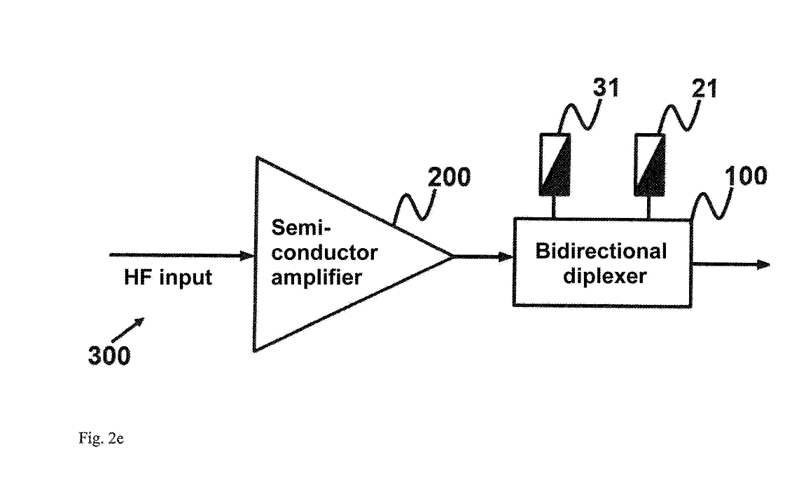

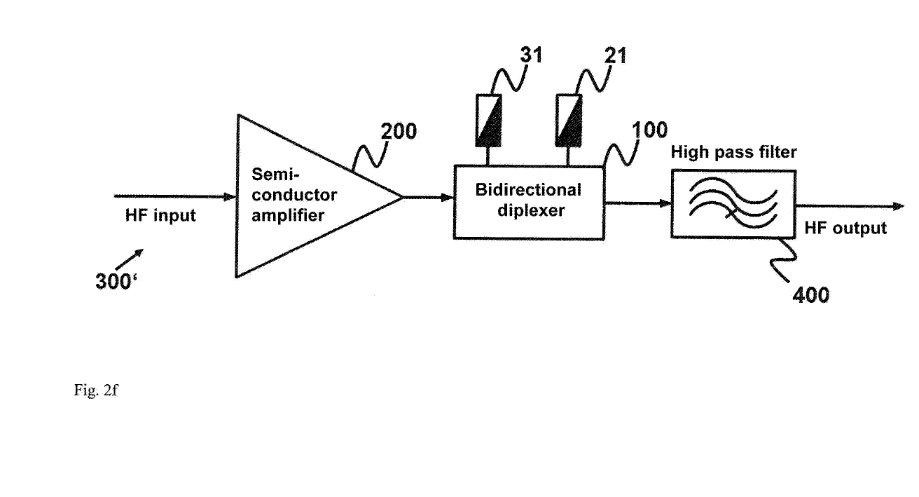

FIG. 2a, FIG. 2b, FIG. 2c and FIG. 2d show schematically some examples of an amplifier module in the CRE312B amplifier.

The amplifier module 600 in FIG. 2a comprises two levels of Wilkinson splitters 610, four amplifier branches 300 and two levels of Wilkinson combiners 620.

The amplifier module 500 in FIG. 2b comprises two levels of hybrid splitters 510, four amplifier branches 300 (see FIG. 2e) and two levels of hybrid combiners 520. The amplifier module 500′ in FIG. 2c and 500″ in FIG. 2d represent variants of the amplifier module 500, with one or more high-pass filters 400 as protective filters.

The amplifier module 500′ in FIG. 2c also comprises two levels of hybrid splitters 510 and two levels of hybrid combiners 520. In addition, the amplifier module 500′ comprises four modified amplifier branches 300′ (see FIG. 2f), in each of which there is a high-pass filter 400 as protective filter arranged at the output of the amplifier branch.

The amplifier module 500″ in FIG. 2d also comprises 2 levels of hybrid splitters 510 and two levels of hybrid combiners 520 as well as four amplifier branches 300. In the amplifier module 500″ the high-pass filter 400 is inserted as protective filter between the last level of the hybrid combiners 520 and the output of the amplifier module 500″.

Therein, the cutoff frequency of the high-pass filter 400 is below the fundamental frequency of the CRE312B amplifier of 72 Mhz. The high-pass filter 400 stands here as an example of a first order filter and is formed by two capacitors (C=47.5 pF) and one inductor (L=107 nH) in a T-network, so that the cutoff frequency of the high-pass filter 400 is approx. 65 MHz. Such a first order high-pass filter provides attenuation of approx. −6 dB at 40 MHz, approx. −14 dB at 30 MHz, approx. −25 dB at 20 MHz, approx. −44 dB at 10 MHz and approx. −62 dB at 5 MHz.

In both the amplifier module 500′ and the amplifier module 500″, the high-pass filter therefore attenuates the (lower frequency) interference signal portions with a frequency below the cutoff frequency of 65 MHz of an interference signal travelling from the output of the amplifier module (or from the amplifier output of amplifier CRE312B) towards the amplifier units or the semiconductor amplifier units 200.

90° hybrid combiners provide an excellent match to the common output port, also in the case of tuning to individual semiconductor amplifier units or amplifier branches for maximum output power, for maximum efficiency and maximum amplification. In addition, 90° hybrid combiners have a very minor reduction in the insulation between individual semiconductor amplifiers or amplifier branches in the event of a mismatched load at the common port, as well as greater immunity for the semiconductor amplifier units or amplifier branches due to their combination in a 90° hybrid combiner than is the case of a stand-alone semiconductor amplifier or amplifier branch. 90° hybrid combiners have narrower bandwidth than Wilkinson combiners.

Wilkinson combiners with an output port set to a load of 50Ω, require a matching to the semiconductor amplifier units or amplifier branches to 50Ω, otherwise a Wilkinson combination is ineffective. But a change to this matching applies if the semiconductor amplifier units or amplifier branches are run under different operational conditions. In addition, using Wilkinson combiners can lead to a reduction in the insulation between the input ports, if there is mismatch of the output ports. An advantage of the Wilkinson combiner is its symmetrical construction and the simplicity of its design.

FIG. 2e shows schematically an amplifier branch 300 of the amplifier module 600, 500 and 500″. The amplifier branch 300 comprises at least two elements: the amplifier unit or the semiconductor amplifier unit 200 in the design of a push-pull amplifier with the LDMOS Transistor BLF 574 and the bidirectional diplexer 100 with the two load resistors 21 and 31. For the structure and characteristics of the BLF 574 transistor from NXP, we refer to the data sheet BLF574, HF/VHF power LDMOS transistor, Rev. 02-24 Feb. 2009, Product data sheet” that is currently available at the URL “http://www.nxp.com/documents/data_sheet/BLF574.pdf”.

The bidirectional diplexer 100 is a further developed version of the classic diplexer, in particular for use in a semiconductor amplifier for the HF supply of an accelerator resonator.

FIG. 2f shows schematically a modified amplifier branch 300′ of the amplifier module 500′. The modified amplifier branch 300′ comprises, in addition to the amplifier unit or the semiconductor amplifier unit 200, the bidirectional diplexer 100 with the two load resistors 21 and 31 and the high-pass filter 400 as a protective filter. The high-pass filter 400 is inserted between the bidiplexer 100 and the output of the amplifier branch.

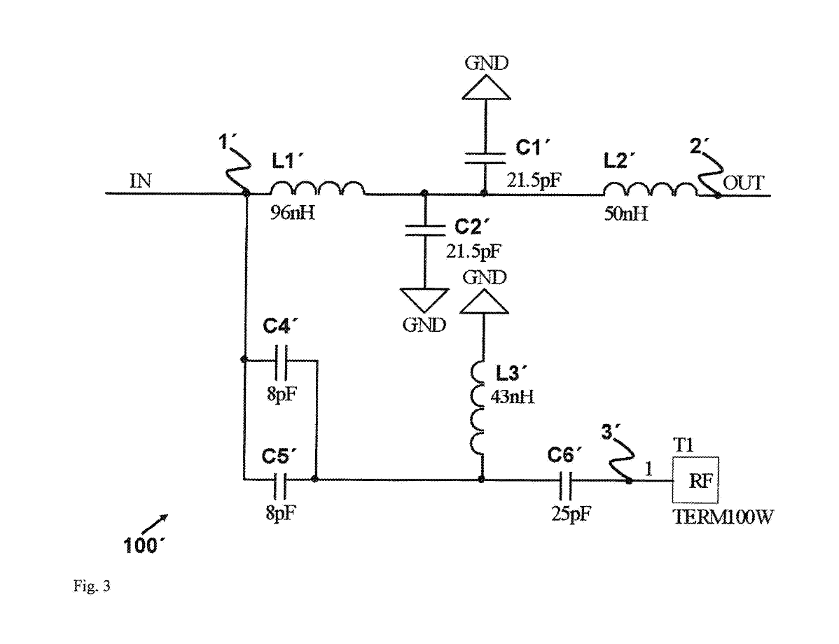

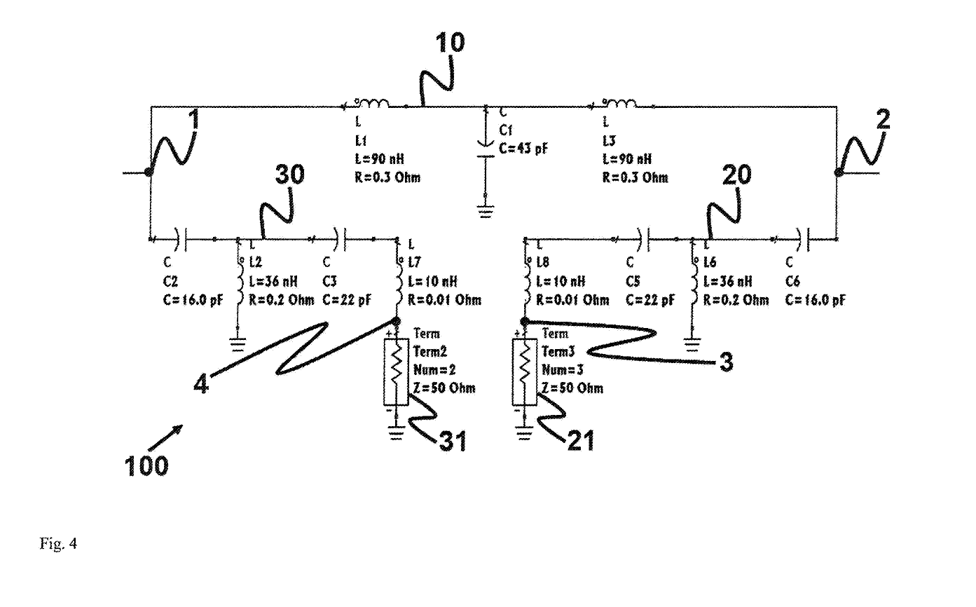

The classic diplexer 100′ shown in FIG. 3 is a multiplexer that links an input (IN) with two outputs (OUT, RF). The classic diplexer 100′ is a crossover unit and has the task of decoupling two frequency ranges from each other. To do this, the classic diplexer 100′ has a high-pass filter and a low-pass filter. The low-pass filter is arranged between input node 1′ and output node 2′ and may, for example, be implemented by the network of inductors L1′ (L=96 nH) and L2′ (L=50 nH) along with capacitors C1′ (C=21.5 pF) and C2′ (C=21.5 pF) shown in FIG. 3. The high-pass filter is inserted between input node 1′ and output node 3′ and may, for example, be implemented by the network of inductor L3′ (L=43 nH) together with capacitors C4′ (C=8 pF), C5′ (C=8 pF) and C6′ (C=25 pF) shown in FIG. 3.

The fundamental frequency of the semiconductor amplifier unit 200 of 72 MHz, and thus the fundamental frequency of the fundamental wave of the output signal of the semiconductor amplifier unit, is transmitted with as little attenuation as possible between the input of the classic diplexer and the output of the diplexer, while all higher frequencies, in particular the second and third harmonics are fed into a load resistor. In this special diplexer all HF signals with frequencies that are significantly higher than the fundamental frequency are absorbed in a load resistor.

The 120 MHz-“Crossover Diplexer” 100′ in FIG. 3 weakens the fundamental frequency of 72 MHz by approx. −0.1 dB, the second harmonic at 144 MHz by approx. −9.5 dB, and the third harmonic at 216 MHz by approx. −19 dB. The reflected signal at the diplexer 100′ lies within the overall frequency range 20 dB below the incoming signal.

A special feature of the CRE312B amplifier is its use of the inventive bidirectional diplexer 100 or bidiplexer 100, at the output of each semiconductor amplifier unit for protection of the power transistors in the semiconductor amplifying unit. The circuit schematic of an example of a bidiplexer 100 is shown in FIG. 4. The parameters shown for the components are only to be understood as examples.

The bidiplexer 100 has a first input and/or output node 1, a second input and/or output node 2, a third node 3 and a fourth node 4. The first input and/or output node 1 and the second input and/or output node 2 are electrically connected to each other by pass-through filter section 10. The second input and/or output node 2 and the third node 3 are electrically connected to each other by the first absorption filter section 20. The first input and/or output node 1 and the fourth node 4 are electrically connected to each other by the second absorption filter section 30.

In the pass-through filter section 10, there is a pass-through filter with low-pass characteristics (i.e. a low-pass filter) formed by inductors L1 (e.g. L=90 nH) and L3 (e.g. L=90 nH) together with capacitor C1 (e.g. C=43 pF). Inductors L1 and L3 and capacitor C1 are arranged in a T-network. In the first absorption filter section 20 there is a first high-pass filter formed by inductors L6 (e.g. L=36 nH) and L8 (e.g. L=10 nH) and capacitors C5 (e.g. C=22 pF) and C6 (e.g. C=25 pF). Such a first order high-pass filter provides attenuation of approx. −6 dB at 40 MHz, approx. −14 dB at 30 MHz, approx. −25 dB at 20 MHz, approx. −44 dB at 10 MHz and approx. −62 dB at 5 MHz. Capacitors C5 and C6 and inductor L6 are arranged in a T-network, wherein capacitor C6 is directed to the second input and/or output node 2 and capacitor C5 is directed to the third node 3. Inductor L8 is inserted between capacitor C5 and the third node 3. In the second absorption filter section 30 there is a second high-pass filter formed by inductors L2 (e.g. L=36 nH) and L7 (e.g. L=10 nH) and capacitors C3 (e.g. C=22 pF) and C2 (e.g. C=16 pF). The connection of inductors L2 and L7 and capacitors C3 and C2 of the second high-pass filter matches the connection of inductors L6 and L8 and capacitors C5 and C6 of the first high-pass filter described above.

The first absorption filter section 20 terminates in the load resistor 21 (e.g. R=50Ω), which is arranged at the third node 3. The second absorption filter section 30 terminates in the load resistor 21 (e.g. R=50Ω), which is arranged at the third node 3.

The bidirectional diplexer 100 in FIG. 4 appears to HF signals that arrive from the semiconductor amplifier unit and to HF signals arriving from the cyclotron's resonator similar.

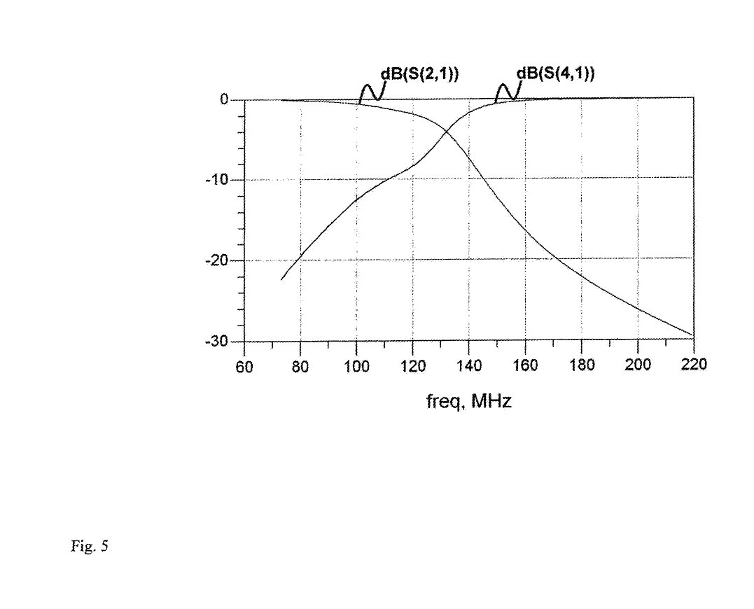

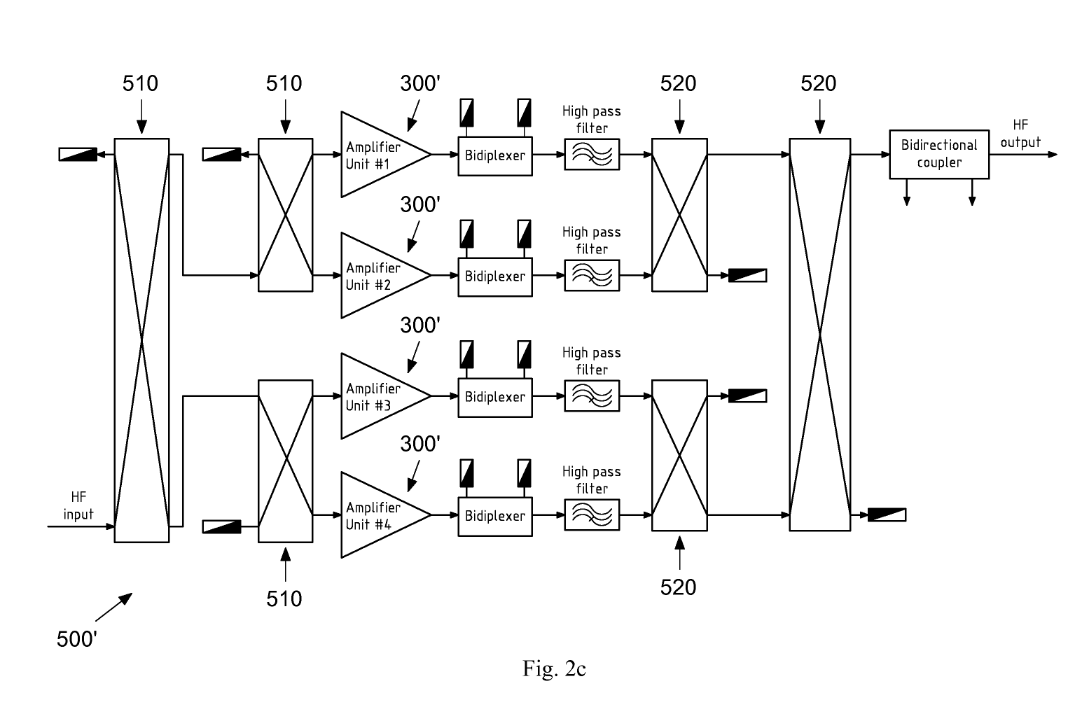

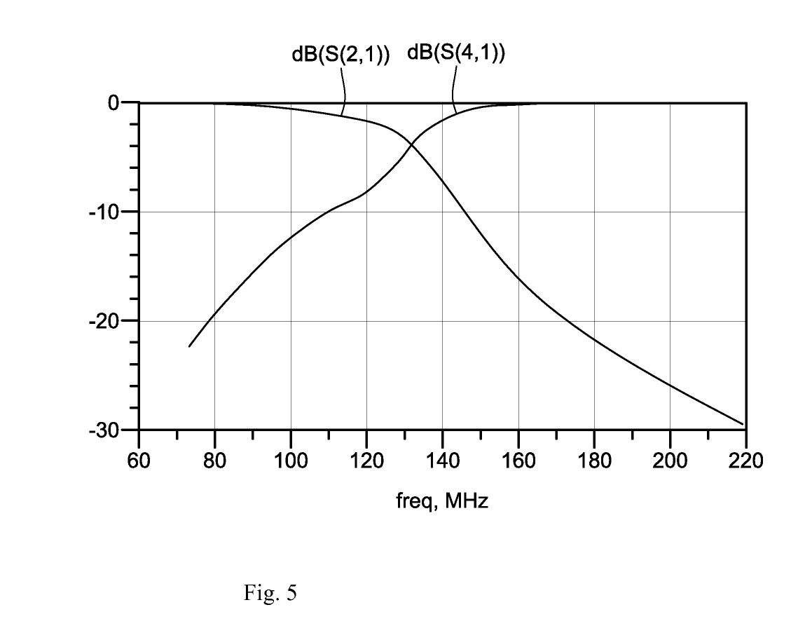

The “bidirectional 130 MHz-Crossover bidiplexer” in FIG. 4, so bidiplexer 100, attenuates the fundamental frequency of 72 MHz by approx. −0.15 dB, the second harmonic 144 MHz by approx. −10.5 dB, and the third harmonic of 216 MHz by approx. −25 dB. These attenuation characteristics of bidiplexer 100 for a signal transmitted from the first input and/or output node 1 to the second input and/or output node 2, (i.e. a signal passed along pass-through filter section 10) can also be deduced from the frequency response dB(S(2.1)) in FIG. 5. The attenuation characteristics of bidiplexer 100 for a signal transmitted from the first input and/or output node 1 to the fourth node 4, (i.e. a signal passed along absorption filter section 30) can be deduced from the frequency response dB(S(4.1)) in FIG. 5. The signal reflected at the diplexer 100 lies within the overall frequency range 20 dB below the incoming signal.

The importance of bidiplexer 100 for the protection of the power transistor in the amplifier unit or the semiconductor amplifier unit 200 has two aspects: avoiding reflected harmonics and absorbing the high frequency emissions from the accelerator resonator.

The output signal of the push-pull amplifier (i.e. the semiconductor amplifier unit 200) is not free of harmonics. The power contained in these harmonics is not useful, and it can be separated out in bidiplexer 100, at least for the main part, and absorbed in a terminal load resistor. This power can therefore no longer be reflected back to the power transistor, thus avoiding damaging additional heating of the junction of the transistor.

As described in detail in the above section “Background to the invention”, in accelerator resonators free electron streams and electrons can arise, in particular from sudden gas discharges and arcing, interference signals with high voltage amplitudes (e.g. interference signals with voltage amplitudes of 130 V or more, in particular with voltage amplitudes of 150 V or more).

The threat to the CRE312B amplifier from this undesired operating condition is reduced by the use of bidiplexer 100. Bidiplexer 100 works as a power divider for the interference signals that come from the accelerator resonator. The influence of the bidirectional coupling becomes more effective, the higher the frequency of the resonator signal rises above the fundamental frequency of the semiconductor amplifier unit. The benefit of bidiplexer 100 consists, among other things, of the fact that both the higher harmonics generated by the amplifier (i.e. in particular interference signal portions with a frequency above the cutoff frequency of the pass-through filter) and those of an interference signal from the accelerator resonator are attenuated. This means that it can ensure protection of the power transistors of the semiconductor amplifier unit 200 against these interference signal portions.

Bidiplexer 100 is therefore eminently suitable for use in a VHF amplifier like the CRE312B amplifier.

Alongside the undesirable higher frequency interference signals there may, as explained above, also be generation of lower frequency interference signals in the accelerator resonator, that can also lead to the destruction of the power transistors in the amplifier units. In addition to bidiplexer 100, therefore, there can also be one (see amplifier module 500″) or several high-pass filters 400 (see amplifier module 500′), (and/or one or more or more band-pass filters) deployed as protective filters in the CRE312B amplifier. The benefit of the high-pass filter 400 lies, among other things, in the fact that lower frequency interference signal portions (i.e. in particular interference signal portions with a frequency below the cutoff frequency of 65 MHz) of an interference signal emitted by the accelerator resonator are attenuated. This can ensure additional protection for the power transistors of the semiconductor amplifier unit 200 against these interference signal portions.

Alternatively, or in addition to this, the power transistors of the amplifier unit can be protected by the use of 90° hybrid combiners, that have narrower bandwidth than Wilkinson combiners, against the interference signals originating in the accelerator resonator.

This makes it possible to provide multiple levels of protection in the CRE312B amplifier to protect the power transistors of the semiconductor amplifier unit 200 against interference signals. Amplifier module 500′ in FIG. 2c comprises, for example, four such protection levels, namely bidiplexer 100 (1st protection level), the high-pass filter 400 (2nd protection level), the first level 90° hybrid combiner (3rd protection level), and the second level 90° hybrid combiner (4th protection level).

In a particularly simple embodiment of the CRE312B amplifier it can basically also be envisaged that the bidiplexer 100 and the high-pass filter 400 are completely dispensed with, if a 90° hybrid combiner is used as a signal combiner. Such a simple embodiment would only ensure protection of the power transistors in the semiconductor amplifier units 200 against interference signal portions arising from interference signals emitted by the accelerator resonator, due to the narrow band transmission function of the 90° hybrid combiner.

In another simple embodiment of the CRE312B amplifier it can also basically be envisaged that the bidiplexer 100 (see FIG. 2t) is completely omitted and only the high-pass filter 400 is used as a protective filter. In this case the high-pass filter 400 can, for example, be inserted in one or more (e.g. all) amplifier branches and/or behind one level of combiners (for example behind the last level of combiners). Such a simple embodiment would only ensure protection of the power transistors in the semiconductor amplifier units 200 against lower frequency interference signal portions arising from interference signals emitted by the accelerator resonator. As under some circumstances lower frequency interference signal portions could predominate, this in particular simple embodiment could provide sufficient protection.

In another simple embodiment of the CRE312B amplifier, it can basically be envisaged that, instead of the bidiplexer 100 the diplexer 100′ is used in combination with the high-pass filter to protect the power transistors in the semiconductor amplifying unit. Such a simple embodiment would ensure protection of the power transistors in the semiconductor amplifier units 200 against lower frequency interference signal portions arising from interference signals emitted by the accelerator resonator, and against reflected harmonics of the output signal from the semiconductor amplifier units 200.

The invention has been described by exemplary embodiments. Some features of these exemplary embodiments should, however, not be regarded as significant for the invention, unless explicitly highlighted. The present invention is not restricted to the specific CRE 3128 semiconductor amplifier and/or the BLF574 transistor; it can equally well be applied for any transistor-based semiconductor amplifier.

1. Circuit arrangement, comprising:
a pass-through filter section between a first input and/or output node and a second input and/or output node, wherein a pass-through filter with low-pass characteristics is arranged in said pass-through filter section,
a first absorption filter section between said first input and/or output node and a third node, wherein a first high-pass filter is arranged in said first absorption filter section, and wherein a first load resistance is arranged at said third node, and
a second absorption filter section between said first input and/or output node and a fourth node, wherein a second high-pass filter is arranged in said second absorption filter section, and wherein a second load resistor is arranged at said fourth node.

2. Circuit arrangement according to claim 1, wherein said pass-through filter and/or said first high-pass filter and/or said second high-pass filter are second or a higher order filters.

3. Circuit arrangement according to claim 1, wherein said pass-through filter and/or said first high-pass filter and/or said second high-pass filter are passive filters.

4. Circuit arrangement according to claim 1, wherein said pass-through filter is formed by at least two inductors and at least one capacitor in a T-network, and/or wherein said first and second high-pass filter each are formed by at least two capacitors and at least one inductor in a T-network.

5. Circuit arrangement according to claim 1, wherein said first and second load resistors each match the characteristic impedance.

6. Apparatus, in particular amplifier module for a VHF amplifier, comprising one or more amplifier branches, wherein each amplifier branch comprises a circuit arrangement according to claim 1.

7. Apparatus according to claim 6, wherein said apparatus comprises multiple amplifier branches.

8. Apparatus according to claim 6, wherein said first or said second input and/or output node of said circuit arrangement according to claim 1 are connected to the output of said amplifier unit.

9. Apparatus according to claim 6, wherein each of the output signals of two or more amplifier branches of said one or more amplifier branches are combined by a signal combiner, in particular a 90° hybrid combiner, to a single signal.

10. Apparatus, in particular a VHF amplifier, comprising:
one or more amplifier branches, wherein each amplifier branch comprises a circuit arrangement according to claim 1 and one amplifier unit,
an output, and
one or more protective filters, wherein said protective filters are inserted between said amplifier units of said amplifier branches and said output.

11. Apparatus according to claim 10, wherein said apparatus comprises multiple amplifier branches.

12. Apparatus according to claim 10, further comprising:
a first level of signal combiners, wherein said first level of signal combiners comprises one or more signal combiners, in particular one or more 90° hybrid combiners, wherein said signal combiners of said first level of signal combiners are arranged between said amplifier branches and said output.

13. Apparatus according to claim 10, wherein each amplifier branch further comprises one of said protective filters.

14. System, comprising:
an apparatus according to claim 10, and
a particle accelerator, wherein an accelerator resonator of said particle accelerator is connected to an output of said apparatus.

15. Use of one or more circuit arrangements according to claim 1 in an amplifier for a particle accelerator for protecting the amplifier units of said amplifier against interference signals emitted by the accelerator resonator and travelling to said amplifier.
